(19) United States
(12) Patent Application Publication
(10) Pub. No.: US 2026/0104464 A1
(43) Pub. Date: Apr. 16, 2026

(54) PREDICTION DEVICE, ENERGY STORAGE APPARATUS, PREDICTION METHOD, AND PREDICTION PROGRAM

(71) Applicant: GS Yuasa International Ltd., Kyoto-shi (JP)

(72) Inventors: Satoshi KUNITA, Kyoto-shi (JP); Seiji TAKAI, Kyoto-shi (JP); Atsushi FUKUSHIMA, Kyoto-shi (JP); Yusuke YOSHIOKA, Kyoto-shi (JP)

(21) Appl. No.: 19/418,483

(22) Filed: Dec. 12, 2025

Related U.S. Application Data
(63) Continuation of application No. PCT/JP2024/021137, filed on Jun. 11, 2024.

(30) Foreign Application Priority Data
Jun. 15, 2023 (JP) 2023-098736

(51) Int. Cl. G01R 31/367; G01R 31/382

(52) U.S. Cl. CPC G01R 31/367; G01R 31/382

(57) ABSTRACT

A prediction device includes a controller configured or programmed to include a first predictor configured or programmed to predict voltage behavior of an energy storage device when a current is carried with a current carrying pattern including sections, using an energy storage device model, and a second predictor configured or programmed to predict charge-discharge performance of the energy storage device based on the voltage behavior predicted by the first predictor. The first predictor is configured or programmed to predict the voltage behavior for each of the sections obtained by dividing the current carrying pattern by a time width, and the first predictor stops predicting the voltage behavior in one of the sections in which a current change amount in the current carrying pattern is less than a threshold.

### CROSS REFERENCE TO RELATED APPLICATIONS

This application claims the benefit of priority to Japanese Patent Application No. 2023-098736 filed on Jun. 15, 2023 and is a Continuation Application of PCT Application No. PCT/JP2024/021137 filed on Jun. 11, 2024. The entire contents of each application are hereby incorporated herein by reference.

### BACKGROUND OF THE INVENTION

### 1. Field of the Invention

The present invention relates to prediction devices, energy storage apparatuses, prediction methods, and non-transitory computer-readable media including prediction programs.

### 2. Description of the Related Art

In order to realize a self-driving feature and a safety feature in a movable body, a need exists for estimation of electric power supply performance of an energy storage device mounted on a vehicle or the like.

A battery control device disclosed in JP-A-2015-114135 simulates charge-discharge behavior of a storage battery by using an electrical equivalent circuit of the storage battery, thereby calculating chargeable-dischargeable electric power of the storage battery.

### SUMMARY OF THE INVENTION

In the case of predicting charge-discharge behavior of an energy storage device when a current is carried with a current carrying pattern using an energy storage device model such as an equivalent circuit, the current carrying pattern is divided by a predetermined unit time, and a voltage is obtained at each predetermined time. By increasing the unit time for dividing the current carrying pattern, the number of calculations can be reduced and prediction time can be shortened, whereas prediction accuracy deteriorates. A need exists for a technique that enables both shortening of the prediction time and improvement of the prediction accuracy.

Example embodiments of the present invention provide techniques to enable both shortening of prediction time and improvement of prediction accuracy.

A prediction device according to an example embodiment of the present disclosure includes a controller configured or programmed to include a first predictor configured or programmed to predict voltage behavior of an energy storage device when a current is carried with a current carrying pattern including sections, using an energy storage device model, and a second predictor configured or programmed to predict charge-discharge performance of the energy storage device based on the voltage behavior predicted by the first predictor, wherein the first predictor is configured or programmed to predict the voltage behavior for each of the sections, obtained by dividing the current carrying pattern by a time width, and the first predictor is configured or programmed to stop predicting the voltage behavior in one of the sections in which a current change amount in the current carrying pattern is less than a threshold.

Example embodiments of the present disclosure enable both shortening of prediction time and improvement of prediction accuracy.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a diagram illustrating an example of a discharge pattern.

FIG. 2 is a diagram illustrating an example of discharge pattern data corresponding to the discharge pattern of FIG. 1.

FIG. 3 is a perspective view illustrating a configuration example of an energy storage apparatus.

FIG. 4 is an exploded perspective view of the energy storage apparatus.

FIG. 5 is a block diagram illustrating a configuration example of the energy storage apparatus including a prediction device.

FIG. 6 is a circuit diagram illustrating an example of an energy storage device model.

FIG. 7 is a diagram illustrating an example of an adjusted discharge pattern.

FIG. 8 is a diagram illustrating an example of adjusted discharge pattern data corresponding to the discharge pattern of FIG. 7.

FIG. 9 is a flowchart illustrating an example of an adjustment processing procedure of a current carrying pattern executed by the prediction device.

FIG. 10 is a flowchart illustrating an example of a prediction processing procedure of current carrying feasibility executed by the prediction device.

### DETAILED DESCRIPTION OF THE EXAMPLE EMBODIMENTS

(1) A prediction device according to an example embodiment of the present disclosure includes a controller configured or programmed to include a first predictor configured or programmed to predict voltage behavior of an energy storage device when a current is carried with a current carrying pattern including sections, using an energy storage device model, and a second predictor configured or programmed to predict charge-discharge performance of the energy storage device based on the voltage behavior predicted by the first predictor. The first predictor is configured or programmed to predict the voltage behavior for each of the sections, obtained by dividing the current carrying pattern by a time width, and the first predictor is configured or programmed to stop predicting the voltage behavior in one of the sections in which a current change amount in the current carrying pattern is less than a threshold. In other words, the first predictor does not predict the voltage behavior in an in-between section of a plurality of temporally-continuous sections in which the current change amount in the current carrying pattern is less than the threshold.

Here, the “energy storage device” may be an energy storage cell or an energy storage assembly including a plurality of energy storage cells.

The “current carrying pattern” may be, for example, a current pattern based on a current value and a current carrying time.

The energy storage device mounted on a movable body preferably always exhibits predetermined charging capability or discharging capability in order to reliably operate a self-driving feature and a safety feature. For example, the energy storage device preferably exhibits predetermined discharging capability with respect to an electrical load connected to the energy storage device whenever discharge is requested. The prediction device preferably predicts current carrying feasibility with the current carrying pattern in a preset calculation cycle.

The prediction device obtains a predicted voltage value of the energy storage device when a current is carried with the current carrying pattern using the energy storage device model, and predicts discharge feasibility based on the obtained predicted voltage value. In the calculation of the predicted voltage value, the current carrying pattern is divided by a division time having the time width, and the predicted voltage value is sequentially calculated for each section.

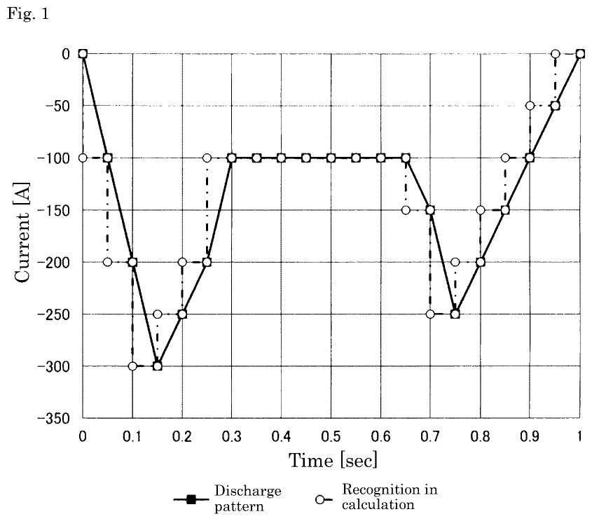

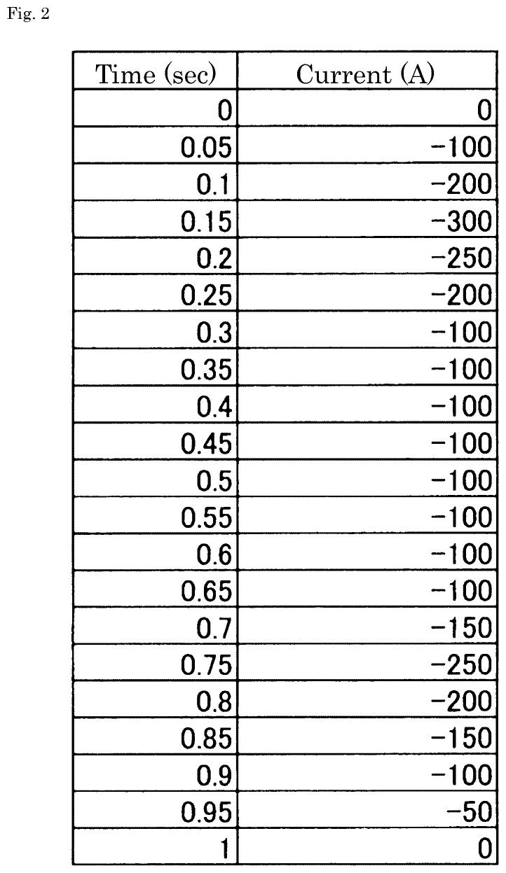

FIG. 1 is a diagram illustrating an example of a discharge pattern, and FIG. 2 is a diagram illustrating an example of discharge pattern data corresponding to the discharge pattern of FIG. 1. In the graph illustrated in FIG. 1, the vertical axis represents a current (unit: ampere (A)), and the horizontal axis represents an elapsed time (unit: second(s)). In FIGS. 1 and 2, the discharge pattern is shown as the current carrying pattern. In FIGS. 1 and 2, the plus side of the current is charge power, and the minus side is discharge power.

In the discharge pattern indicated by the black squares and the solid line in FIG. 1, with a current value at a start time point (0 seconds) as zero, a discharge current value (an absolute value of the current value) gradually increases from 0 seconds to 0.15 seconds, the discharge current value gradually decreases from 0.15 seconds to 0.3 seconds, the current value is constant from 0.3 seconds to 0.65 seconds, the discharge current value gradually increases from 0.65 seconds to 0.75 seconds, and the discharge current value gradually decreases from 0.75 seconds to an end time point (1 second), for example.

The discharge pattern data of FIG. 2 is obtained by recording the current value in the discharge pattern at each predetermined division time. In the examples of FIGS. 1 and 2, the division time is 0.05 seconds, for example.

In the energy storage device model, a voltage value after carrying a current in a case where the current is carried at a constant current value for a predetermined time is predicted. At the time of calculating the predicted voltage using the energy storage device model, the voltage value within each division time is recognized as constant. In FIG. 1, the white circles and the alternate long and short dash line indicate a recognition pattern at the time of calculation recognized based on the discharge pattern.

The discharge current value from 0 seconds to 0.05 seconds gradually increases from 0 A to 100 A in the actual discharge pattern, but is recognized as constant 100 A at the time of calculation, for example. The deviation in recognition of the current value causes deviation between a consumption capacity of the discharge pattern and a consumption capacity at the time of calculation. The deviation in consumption capacity causes deterioration in prediction accuracy of the predicted voltage value by the energy storage device model. In a case where the current carrying pattern includes a section with a current change, the prediction accuracy of the predicted voltage value deteriorates. As a total current carrying time of the current carrying pattern is longer, the deviation in consumption capacity becomes larger, and thus the degree of deterioration of the prediction accuracy caused by the current carrying pattern with a current change becomes larger.

In order to improve the prediction accuracy of the current carrying pattern with a current change, it is preferable to shorten the division time. However, shortening the division time increases the number of calculations, resulting in an increase in calculation cost and prediction time. In a case where there is a plurality of types of current carrying patterns to be predicted, prediction is necessary for each current carrying pattern, resulting in a further increase in load.

If the number of calculations increases, there is a possibility that prediction at all time points in a specific calculation cycle cannot be completed within an allowable time allowed for the prediction processing of discharge feasibility. In order to complete the prediction within the allowable time, it is conceivable to shorten the calculation cycle or lengthen the division time of the discharge pattern to reduce the number of calculations. Shortening the calculation cycle is undesirable because it increases a load on the prediction device, and there is a limit in terms of performance. Lengthening the division time leads to deterioration in the prediction accuracy because the original current carrying pattern is not properly reflected. For example, in a case where the division time of the discharge pattern illustrated in FIG. 1 is set to 0.1 seconds, discharge pattern data is obtained in which the current is −200 A at 0.1 seconds and then −250 A at 0.2 seconds, and −300 A at 0.15 seconds is not reflected. In the case of the division time of 0.1 seconds, the lowest value of the predicted voltage value becomes higher than that of the division time of 0.05 seconds, for example, leading to deterioration in the prediction accuracy of the discharge feasibility.

According to the prediction device described in the above (1), no calculation processing for voltage prediction is performed in an in-between section of a period in which the current change amount in the current carrying pattern is less than the threshold, so that the number of calculations as a whole can be reduced. By shortening the division time, it is possible to shorten the prediction time while improving the prediction accuracy. The prediction device may predict the voltage behavior over the plurality of continuous sections in one calculation processing by joining the plurality of temporally-continuous sections in which the current change amount is less than the threshold into one new section. By reducing the number of calculations only during the period in which the current change amount is less than the threshold, it is possible to efficiently perform an arithmetic operation while suppressing deterioration in the prediction accuracy. The charge-discharge performance can be efficiently and accurately predicted based on the voltage behavior predicted in this manner.

(2) In the prediction device according to the above (1), one of the sections of the current carrying pattern has a constant current.

According to the prediction device described in the above (2), it is possible to improve the prediction accuracy regarding the current carrying pattern including the section in which the current is constant, and to reduce an arithmetic load.

(3) In the prediction device according to the above (1) or (2), the first predictor may be configured or programmed to adjust the current carrying pattern based on a consumption capacity or a current at a switching point at which a current increasing/decreasing direction is switched, in one of the sections in which the current change amount in the current carrying pattern is equal to or more than the threshold, and predict the voltage behavior based on the adjusted current carrying pattern.

According to the prediction device described in the above (3), the current value of the current carrying pattern can be adjusted in consideration of the consumption capacity in the current carrying pattern. By adjusting the current carrying pattern, it is possible to eliminate the deviation in the consumption capacity between the current carrying pattern and the recognition at the time of calculation. In addition, the current value of the current carrying pattern can be adjusted in consideration of the current at the switching point at which the current increasing/decreasing direction is switched. Since a maximum value or a minimum value of the current can be reflected in the adjustment of the current carrying pattern, it is possible to avoid predicting the lowest voltage value higher than an actual value or the highest voltage value lower than an actual value. The prediction accuracy regarding the current carrying pattern including the section with a current change is improved.

(4) In the prediction device according to the above (3), one of the sections in which the current change amount in the current carrying pattern is equal to or more than the threshold may include a section in which the current increasing/decreasing direction is switched and a section in which the current increasing/decreasing direction is not switched, and the first predictor may be configured or programmed to adjust the current carrying pattern based on the current at the switching point in the one of the sections in which the current increasing/decreasing direction is switched and the consumption capacity in the one of the sections in which the current increasing/decreasing direction is not switched.

According to the prediction device described in the above (4), the deviation in the consumption capacity is eliminated by using an electric power value corresponding to the consumption capacity in the section in which the current increasing/decreasing direction is not switched. In addition, in the section in which the current increasing/decreasing direction is switched, a minimum value or a maximum value of the predicted voltage value can be accurately predicted by using the actual current value instead of the adjustment in consideration of the consumption capacity.

(5) In the prediction device according to any one of the above (1) to (4), the sections of the current carrying pattern may include a section in which the current change amount in the current carrying pattern is less than the threshold and a section in which the current change amount is equal to or more than the threshold.

According to the prediction device described in the above (5), it is possible to improve the prediction accuracy regarding the current carrying pattern including a period in which the current hardly changes and a period in which the current changes, and to reduce an arithmetic load. The charge-discharge performance can be efficiently and accurately determined for various current carrying patterns.

(6) The prediction device according to any one of the above (1) to (5) may include an output interface to output the charge-discharge performance of the energy storage device predicted by the second predictor to an external device.

According to the prediction device described in the above (6), it is possible to reliably report the determined charge-discharge performance to the external device.

(7) An energy storage apparatus according to an example embodiment of the present disclosure includes an energy storage device, and the prediction device according to any one of the above (1) to (6).

(8) A prediction method according to an example embodiment of the present disclosure includes predicting voltage behavior of an energy storage device when a current is carried with a current carrying pattern including sections, using an energy storage device model, predicting charge-discharge performance of the energy storage device based on the predicted voltage behavior, predicting the voltage behavior for each of the sections obtained by dividing the current carrying pattern in a time axis direction, and stopping predicting the voltage behavior in one of the sections in which a current change amount in the current carrying pattern is less than a threshold.

(9) A non-transitory computer-readable medium including a prediction program according to an example embodiment of the present disclosure causes a computer to predict voltage behavior of an energy storage device when a current is carried with a current carrying pattern including sections, using an energy storage device model, predict charge-discharge performance of the energy storage device based on the predicted voltage behavior, predict the voltage behavior for each of the sections obtained by dividing the current carrying pattern in a time axis direction, and stop predicting the voltage behavior in one of the sections in which a current change amount in the current carrying pattern is less than a threshold.

(10) A prediction device according to an example embodiment of the present disclosure includes a controller configured or programmed to include a first predictor configured or programmed to predict voltage behavior of an energy storage device when a current is carried with a current carrying pattern including sections, using an energy storage device model, and a second predictor configured or programmed to predict charge-discharge performance of the energy storage device based on the voltage behavior predicted by the first predictor, wherein the first predictor is configured or programmed to divide the current carrying pattern into a plurality of periods and predict the voltage behavior for each of the plurality of periods, and a time width of a period in which a current change amount in the current carrying pattern is less than a threshold is longer than a time width of a period in which the current change amount in the current carrying pattern is equal to or more than the threshold.

According to the prediction device described in the above (10), the length of the time width for executing the prediction calculation of the voltage behavior can be made variable according to the presence or absence of a current change in the current carrying pattern. It is possible to improve calculation efficiency while suppressing deterioration in the prediction accuracy.

Example embodiments of the present disclosure will be specifically described with reference to the drawings.

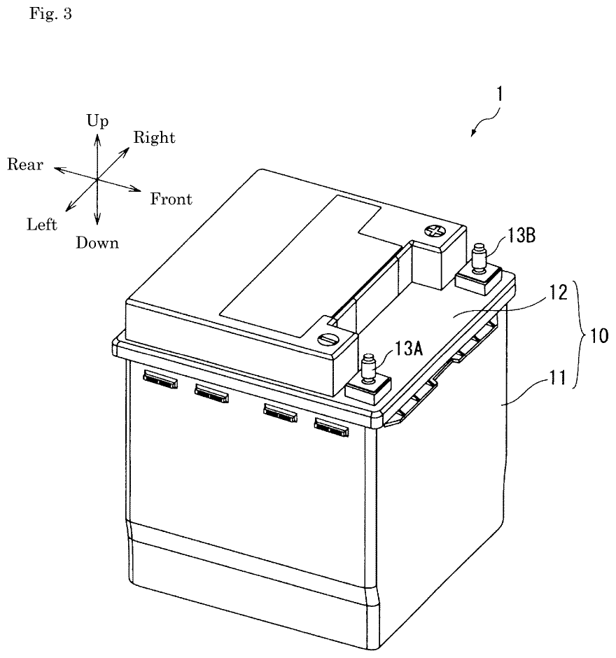

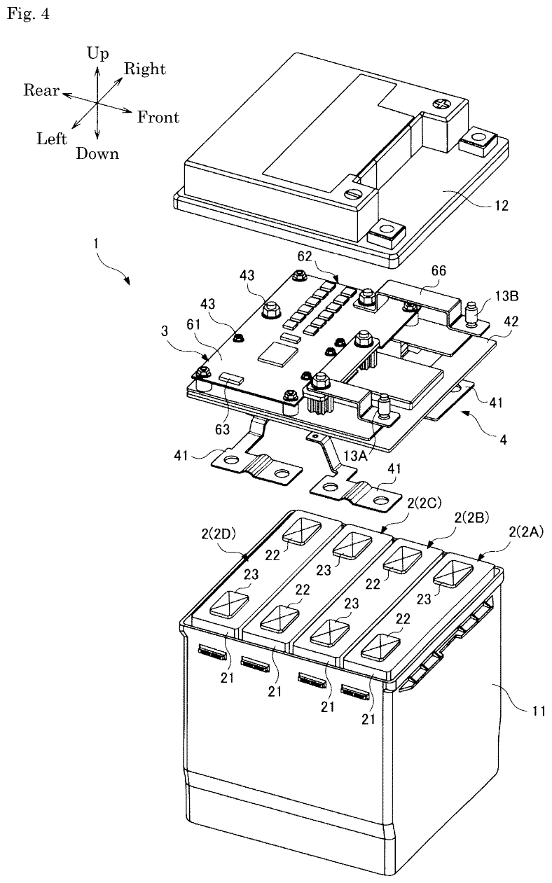

FIG. 3 is a perspective view illustrating a configuration example of an energy storage apparatus 1, and FIG. 4 is an exploded perspective view of the energy storage apparatus 1. Hereinafter, the configuration example of the energy storage apparatus 1 will be described with reference to respective directions of “front and rear”, “left and right”, and “up and down” shown in the drawings.

The energy storage apparatus 1 is a battery suitably mounted on, for example, an engine vehicle, an electric vehicle (EV), a hybrid electric vehicle (HEV), a plug-in hybrid electric vehicle (PHEV), or the like. The energy storage apparatus 1 is, for example, a 12 volt (V) battery or a 48 V battery.

The energy storage apparatus 1 includes a plurality of energy storage cells 2, a prediction device 3, and a bus bar assembly 4. The energy storage apparatus 1 is an example of an energy storage device. The energy storage cells 2, the prediction device 3, and the bus bar assembly 4 are housed inside a housing case 10. Each energy storage cell 2 is, for example, a battery cell of a lithium ion secondary battery.

In the present example embodiment, the energy storage device is an energy storage assembly including the plurality of energy storage cells 2. Alternatively, the energy storage device may be a single energy storage cell 2.

The prediction device 3 is, for example, a battery management system (BMS). The prediction device 3 is configured or programmed to perform charge-discharge feasibility prediction to predict whether or not the energy storage apparatus 1 satisfies charging capability or discharging capability related to a current carrying pattern, that is, charge-discharge performance of the energy storage apparatus 1.

In the present example embodiment, the prediction device 3 is mounted inside the energy storage apparatus 1. Alternatively, the prediction device 3 may be installed separately from the energy storage apparatus 1. The prediction device 3 may be a computer such as a server device, a terminal device, or a vehicle ECU connected to the outside of the energy storage apparatus 1. In this case, measurement data measured with respect to the energy storage apparatus 1 may be transmitted to the server device or the like by communication.

The housing case 10 is made of synthetic resin. The housing case 10 includes a case body 11 whose upper surface is opened and a cover 12 that covers the opening of the case body 11. The case body 11 and the cover 12 are liquid-tightly fixed by a fastener such as a screw, an adhesive, welding, or the like in a state where the energy storage cells 2, the prediction device 3, and the bus bar assembly 4 are housed therein. A pair of external terminals 13A and 13B having different polarities is provided on one side surface of the housing case 10.

Each energy storage cell 2 includes a case 21 having a hollow rectangular parallelepiped shape. A positive terminal 22 and a negative terminal 23 of the energy storage cell 2 are provided on an upper surface of the case 21. An electrode assembly, an electrolyte solution, and the like (not illustrated) are housed in the case 21.

The electrode assembly is configured by stacking a sheet-shaped positive electrode and a sheet-shaped negative electrode with two sheet-shaped separators interposed therebetween and winding (vertically winding or horizontally winding) them. Each separator is formed by a porous resin film. As the porous resin film, a porous resin film made of resin such as polyethylene (PE) or polypropylene (PP) can be used.

The positive electrode is, for example, an electrode plate in which a positive active material layer is formed on the surface of an elongated strip-shaped positive electrode substrate made of aluminum, an aluminum alloy, or the like. The positive active material layer contains a positive active material. As the positive active material used for the positive active material layer, a material capable of storing and releasing lithium ions can be used. Examples of the positive active material include LiFePO₄. The positive active material layer may further contain a conductive additive, a binder, and the like.

The negative electrode is, for example, an electrode plate in which a negative active material layer is formed on the surface of an elongated strip-shaped negative electrode substrate made of copper, a copper alloy, or the like. The negative active material layer contains a negative active material. As the negative active material, a material capable of storing and releasing lithium ions can be used. Examples of the negative active material include graphite, hard carbon, and soft carbon. The negative active material layer may further contain a binder, a thickener, and the like.

An electrolyte similar to that of a conventional lithium ion secondary battery can be used. For example, an electrolyte containing a supporting salt in an organic solvent can be used as the electrolyte. As the organic solvent, for example, an aprotic solvent such as carbonates, esters, or ethers is used. As the supporting salt, for example, a lithium salt such as LiPF₆, LiBF₄, or LiClO₄ is suitably used. The electrolyte may contain, for example, various additives such as a gas generating agent, a film forming agent, a dispersant, and a thickener.

In the present example embodiment, each energy storage cell 2 is a battery cell of a lithium ion secondary battery. Alternatively, the energy storage cell 2 may be a battery cell of an all-solid-state battery, a lead-acid battery, a redox flow battery, a zinc-air battery, an alkaline manganese battery, a lithium-sulfur battery, a sodium-sulfur battery, a silver oxide-zinc battery, a nickel-metal hydride battery, a molten salt thermal battery, or the like, or may be a capacitor.

In the present example embodiment, the energy storage cell 2 is a prismatic battery cell including a wound electrode assembly. Alternatively, the energy storage cell 2 may be a cylindrical battery cell, a laminated (pouch) battery cell, or a battery cell including a layered electrode assembly.

In the present example embodiment, the number of energy storage cells 2 housed in the case body 11 is four, for example. Alternatively, the number of energy storage cells 2 housed in the case body 11 may be one or more to less than four, or may be more than four. In the following description, the energy storage cells 2 are also referred to as a first energy storage cell 2A, a second energy storage cell 2B, a third energy storage cell 2C, and a fourth energy storage cell 2D in this order from the front side of the case body 11.

As illustrated in FIG. 4, the energy storage cells 2 are housed in the case body 11 such that the positive terminal 22 and the negative terminal 23 of the adjacent energy storage cells 2 are reversed in direction.

The prediction device 3 is disposed on terminal surfaces of the energy storage cells 2 with the bus bar assembly 4 therebetween. The bus bar assembly 4 includes a plurality of bus bars 41 and a bus bar frame 42 made of resin and holding the bus bars 41. The bus bars 41 are connected to a lower surface of the prediction device 3 respectively by fasteners 43 such as screws. The energy storage cells 2 and the prediction device 3 are connected together by the bus bars 41.

The bus bars 41 form charge-discharge paths for the energy storage cells 2. The bus bars 41 are made of metal, and are formed by a material having excellent electric conductivity and high thermal conductivity, such as aluminum, an aluminum alloy, copper, a copper alloy, or stainless steel. In the adjacent energy storage cells 2, the bus bar 41 electrically connects the positive terminal 22 of one of the energy storage cells 2 and the negative terminal 23 of the other energy storage cell 2. The bus bars 41 also connect the negative terminal 23 of the first energy storage cell 2A to one of the external terminals 13A, and the positive terminal 22 of the fourth energy storage cell 2D to the other external terminal 13B.

In FIGS. 3 and 4, the configuration has been described where the four energy storage cells 2 are connected in series by the bus bars 41, for example. Alternatively, some or all of the energy storage cells 2 may be connected in parallel.

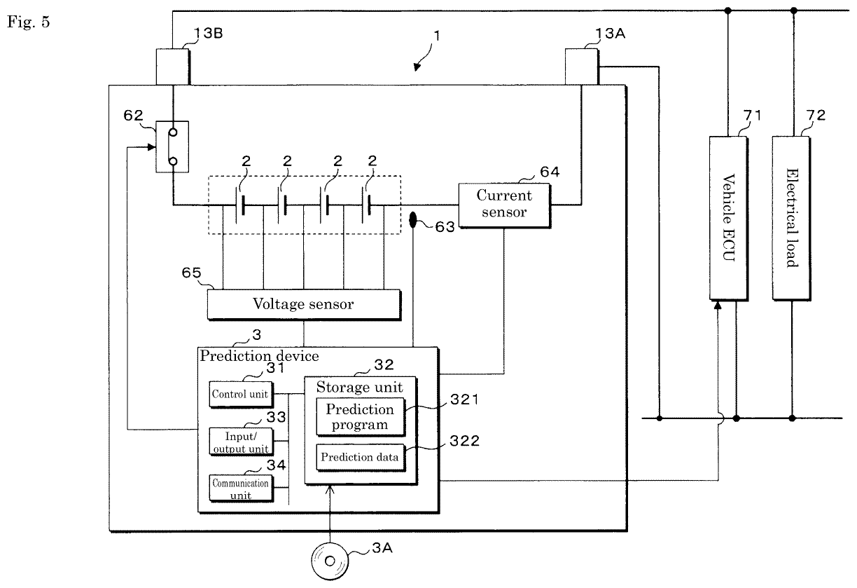

The prediction device 3 includes a circuit board 61 having a flat plate shape. A cutoff circuit 62, a temperature sensor 63, a current sensor 64, a voltage sensor 65 (see FIG. 5), and the like are also mounted on an upper surface of the circuit board 61. The prediction device 3 may be configured as a circuit board assembly in which the cutoff circuit 62, the temperature sensor 63, the current sensor 64, and the voltage sensor 65 are mounted on the circuit board 61.

The cutoff circuit 62 is a circuit to connect or disconnect a conduction path between the bus bar 41, which is connected to the positive terminal 22 of the fourth energy storage cell 2D, and a bus bar 66 connected to the external terminal 13B. The cutoff circuit 62 includes, for example, a semiconductor switch such as a metal oxide semiconductor field effect transistor (MOSFET). By switching the cutoff circuit 62 from an on state to an off state, it is possible to cut off outflow of a current from the energy storage cells 2 to the outside and inflow of a current from the outside to the energy storage cells 2. Alternatively, the cutoff circuit 62 may be configured by a relay switch.

The temperature sensor 63 is, for example, a thermistor, a thermocouple, or the like. The temperature sensor 63 measures a temperature related to the energy storage apparatus 1. In FIG. 4, the temperature sensor 63 is disposed at a position sufficiently separated from a current-carried heat generation body (for example, the cutoff circuit 62, the bus bars 41 and 66, the fasteners 43, and the like) on the circuit board 61. Temperature data measured by the temperature sensor 63 indicates an ambient temperature of the energy storage apparatus 1 (a temperature around the energy storage cells 2). The energy storage device may further include a temperature sensor 63 that is disposed near the current-carried heat generation body on the circuit board 61 to measure a temperature of the current-carried heat generation body on the circuit board 61. In this case, a temperature of the energy storage 1 may be specified based on the ambient temperature of the energy storage apparatus 1 and the temperature of the current-carried heat generation body on the circuit board 61.

FIG. 5 is a block diagram illustrating a configuration example of the energy storage apparatus 1 including the prediction device 3. The energy storage apparatus 1 is connected to a vehicle electronic control unit (ECU) 71, an electrical load 72 such as an electrical component, and an alternator (not illustrated) through the external terminals 13A and 13B.

In a case where the vehicle is an engine vehicle and a power generation amount of the alternator is larger than a power consumption amount of the electrical load 72 during driving of an engine, the energy storage apparatus 1 is charged by the alternator. In a case where the power generation amount of the alternator is smaller than the power consumption amount of the electrical load 72, the energy storage apparatus 1 performs discharge in order to compensate for the shortage. During parking of the vehicle, the alternator stops power generation, so that the energy storage apparatus 1 is not charged and only performs discharge for the vehicle ECU 71 and the electrical load 72.

In a case where the vehicle can start traveling by a high-voltage system (driving energy storage apparatus) instead of the internal combustion engine, the energy storage apparatus 1 supplies electric power for enabling the high-voltage system to start. During parking of the vehicle, the energy storage apparatus 1 performs discharge for the vehicle ECU 71 and the electrical load 72, and can also be charged by the high-voltage system.

The vehicle ECU 71 is a vehicle controller configured or programmed to control the vehicle. The vehicle ECU 71 is configured or programmed to control the electrical load 72. The vehicle ECU 71 is configured or programmed to control a charge or discharge amount of the energy storage apparatus 1 by controlling the electrical load 72 based on a prediction result of charge-discharge feasibility received from the prediction device 3. The vehicle ECU 71 is an example of a host device.

The prediction device 3 is a computer, and includes a controller 31, a storage assembly 32, an input/output interface 33, a communicator 34, and the like. In the present example embodiment, the prediction device 3 may include a circuit board such as the circuit board 61. Alternatively, the prediction device 3 may be configured by a plurality of computers for distributed processing, may be realized by a plurality of virtual machines provided in one server, or may be realized by using a cloud server.

The controller 31 may be an arithmetic circuit including a central processing unit (CPU), a graphics processing unit (GPU), a read only memory (ROM), a random access memory (RAM), and the like. The CPU or the GPU included in the controller 31 executes various computer programs stored in the ROM and the storage assembly 32, and is configured or programmed to control operation of each hardware element described above. The controller 31 may be configured or programmed to perform functions such as a timer that measures an elapsed time from when a measurement start instruction is given to when a measurement end instruction is given, a counter that counts the number, and a clock that outputs date and time information.

The storage assembly 32 includes a nonvolatile storage device such as a flash memory or a hard disk drive. The storage assembly 32 stores various computer programs, data, and the like referred to by the controller 31. The storage assembly 32 may be an external storage device connected to the prediction device 3.

The storage assembly 32 of the present example embodiment stores a prediction program 321 executable to cause a computer to execute processing related to the prediction of charge-discharge feasibility, and prediction data 322 as data necessary for execution of the prediction program 321. The prediction data 322 includes an energy storage device model used in simulation. The energy storage device model is described by configuration information indicating a circuit configuration, a value of each element configuring the energy storage device model, and the like. The storage assembly 32 stores the configuration information indicating the circuit configuration of the energy storage device model, the value of each element configuring the energy storage device model, and the like.

Computer programs (computer program products) including the prediction program 321 may be stored on a non-transitory computer-readable recording medium 3A in which the computer programs are readably recorded. The recording medium 3A is, for example, a portable memory such as a magnetic disk, an optical disk, or a semiconductor memory. The controller 31 reads a desired computer program from the recording medium 3A using a reading device (not illustrated), and causes the storage assembly 32 to store the read computer program. Alternatively, the above computer programs may be provided by communication. The prediction program 321 may be a single computer program or may be configured by a plurality of computer programs, and may be executed on a single computer or may be executed on a plurality of computers interconnected by a communication network.

The input/output interface 33 is an input/output interface to which an external device is to be connected. The cutoff circuit 62, the temperature sensor 63, the current sensor 64, the voltage sensor 65, and the like are connected to the input/output interface 33.

The controller 31 is configured or programmed to output a control signal to the cutoff circuit 62 through the input/output interface 33 to switch the cutoff circuit 62 between the on state and the off state. In addition, the controller 31 configured or programmed to acquire temperature data measured by the temperature sensor 63, current data measured by the current sensor 64, and voltage data measured by the voltage sensor 65 as needed through the input/output interface 33.

The current sensor 64 is, for example, a shunt resistor, and is connected in series to the energy storage cells 2. The current sensor 64 measures a current flowing through the energy storage cells 2 in time series based on an end-to-end voltage of the energy storage cells 2. Discharge and charge can be determined from the polarity (positive or negative) of the end-to-end voltage. Alternatively, the current sensor 64 may be a magnetic sensor.

The voltage sensor 65 is connected in parallel to each energy storage cell 2. The voltage sensor 65 is connected to opposite ends of each energy storage cell 2, and measures an inter-terminal voltage of each energy storage cell 2 in time series. The controller 31 acquires data of the voltage of each energy storage cell 2 measured by the voltage sensor 65 and a total voltage of the energy storage apparatus 1 through the input/output interface 33.

A display device such as a liquid crystal display device may be connected to the input/output interface 33. The controller 31 may output an estimation result of an available SOC range through the input/output interface 33 and cause the display device to display the estimation result.

The communicator 34 includes a communication interface that enables communication with the vehicle ECU 71 or another external device. The controller 31 transmits and receives various data including the prediction result of charge-discharge feasibility to and from the vehicle ECU 71 or the other external device through the communicator 34.

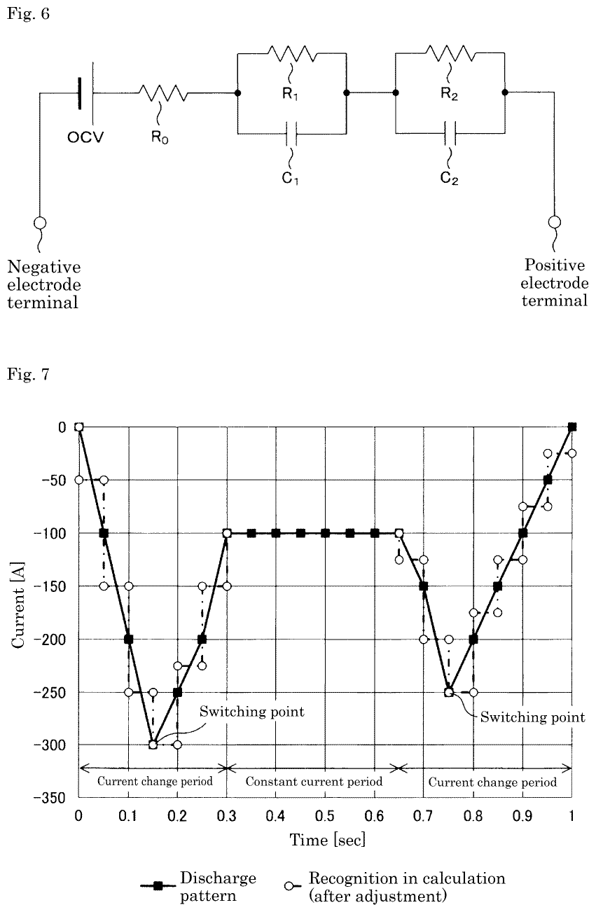

FIG. 6 is a circuit diagram illustrating an example of the energy storage device model. The energy storage device model is used for prediction of voltage behavior of the energy storage apparatus 1.

The energy storage device model illustrated in FIG. 6 is an equivalent circuit model, and simulates charge-discharge behavior of the energy storage cell 2 by combining a voltage source and circuit elements such as a resistor and a capacitor of the energy storage cell 2. The equivalent circuit model includes, for example, a constant voltage source, a direct current resistor, and an RC parallel circuit connected in series between a positive electrode terminal and a negative electrode terminal. FIG. 6 illustrates the equivalent circuit model in which two RC parallel circuits of a first RC parallel circuit and a second RC parallel circuit are connected in series, but the equivalent circuit model is not limited to the two-stage RC parallel circuits.

The constant voltage source is a voltage source that outputs a direct current voltage. The voltage output from the constant voltage source is an open circuit voltage (OCV) of the energy storage cell 2 and is referred to as V_{OCV}. The open circuit voltage V_{OCV} is given, for example, as a function of SOC. The open circuit voltage V_{OCV} may be given as a function of an actual capacity of the energy storage cell 2.

The direct current resistor provides a direct current resistance component (direct current impedance) of the energy storage cell 2, and includes a resistive element R₀. A value of the resistive element R₀ is given as a value that changes according to a carried current, a voltage, SOC, a temperature, or the like. When the value of the resistive element R₀ is determined, a voltage generated in the direct current resistor when a current I flows through the equivalent circuit model can be calculated. The voltage generated in the direct current resistor is referred to as a direct current resistance voltage VRO.

The two RC parallel circuits are circuit elements to define transient polarization characteristics of the energy storage cell 2. The first RC parallel circuit includes a resistive element R₁ and a capacitive element C₁ connected in parallel. The second RC parallel circuit includes a resistive element R₂ and a capacitive element C₂ connected in parallel. Respective values of the resistive elements R₁ and R₂ and the capacitive elements C₁ and C₂ are given as values that vary according to a carried current, SOC, a temperature, or the like. Impedance of the first RC parallel circuit and the second RC parallel circuit is determined by the resistive elements R₁ and R₂ and the capacitive elements C₁ and C₂. When the impedance of the first RC parallel circuit and the second RC parallel circuit is determined, a voltage (polarization voltage) generated in the first RC parallel circuit and the second RC parallel circuit when the current I flows through the equivalent circuit model can be calculated. The polarization voltage is a total voltage of a polarization voltage V₁ generated in the first RC parallel circuit and a polarization voltage V₂ generated in the second RC parallel circuit.

In the equivalent circuit model described above, a terminal voltage (predicted voltage value) V_{cell} between the positive electrode terminal and the negative electrode terminal of the energy storage cell 2 at a time point after t seconds can be expressed by Formula (1) described below using the current I, the open circuit voltage V_{OCV}, the polarization voltage V₁, the polarization voltage V₂, the resistive elements R₀, R₁, and R₂, and the capacitive elements C₁ and C₂.

$$[ Math . 1 ]$$

$${V}_{cell} = {V}_{ocv} + {R}_{0} I + {R}_{1} I \times ( 1 - {exp}^{\frac{- t}{{R}_{1} {C}_{1}}} ) + {V}_{1} \times {exp}^{\frac{- t}{{R}_{1} {C}_{1}}} + {R}_{2} I \times ( 1 - {exp}^{\frac{- t}{{R}_{2} {C}_{2}}} ) + {V}_{2} \times {exp}^{\frac{- t}{{R}_{2} {C}_{2}}} \qquad ( 1 )$$

The respective values of the resistive elements R₀, R₁, and R₂ and the capacitive elements C₁ and C₂ used in the equivalent circuit model are obtained in advance based on actual measurement data or the like.

A predicted voltage value of the energy storage apparatus 1 is obtained by calculating a total value of the predicted voltage values V_{cell} of the respective energy storage cells 2 obtained by Formula (1) described above. The predicted voltage value of the energy storage apparatus 1 may be a value obtained by adding a voltage caused by a resistance component of a conductive member (for example, the bus bars 41 and 66, the cutoff circuit 62, and the like) in the energy storage apparatus 1.

A method of predicting the charge-discharge feasibility using the above energy storage device model executed by the prediction device 3 will be described. Hereinafter, the method of predicting the charge-discharge feasibility will be described by exemplifying a case where the current carrying pattern is a discharge pattern and whether or not predetermined electric power can be supplied (SOF: state of function) is predicted.

When predicting the charge-discharge feasibility, the prediction device 3 acquires information of the discharge pattern to be predicted. The information of the discharge pattern is designated from, for example, the host device. The information of the discharge pattern may include a carried current value, a current carrying time, and an operating voltage range related to the discharge pattern. The carried current value and the current carrying time are given in the form of, for example, discharge pattern data. The discharge pattern data may be data in which the discharge pattern is divided by a time width corresponding to a predetermined division time, and a time (an elapsed time from a start time point) corresponding to each division point and a current value of the time are associated with each other. The operating voltage range is a lower limit voltage of the energy storage apparatus 1 at the time of discharge, and an upper limit voltage of the energy storage apparatus 1 is provided at the time of charge. In one example, the discharge pattern in FIGS. 1 and 2 described above is a prediction target.

The prediction device 3 obtains the predicted voltage value when discharge is performed with the designated discharge pattern using the above-described energy storage device model. The prediction device 3 of the present example embodiment adjusts the discharge pattern acquired from the host device to be suitable for the prediction processing, and predicts the predicted voltage value based on the adjusted discharge pattern. The prediction device 3 reduces the number of calculations in a constant current period of the discharge pattern. The prediction device 3 further adjusts a current value in a current change period of the discharge pattern.

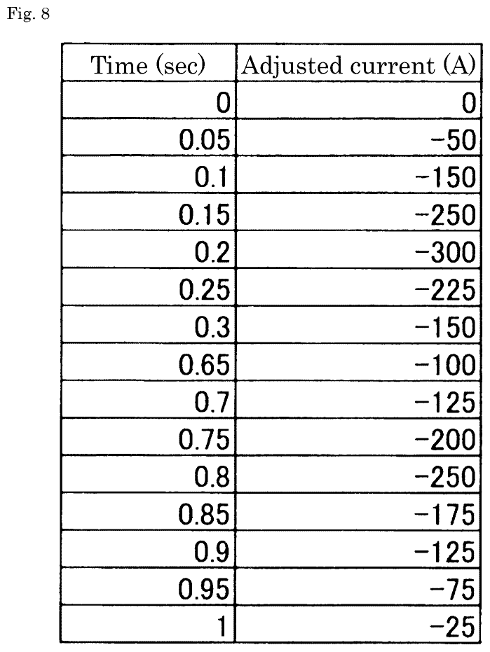

FIG. 7 is a diagram illustrating an example of the adjusted discharge pattern, and FIG. 8 is a diagram illustrating an example of the adjusted discharge pattern data corresponding to the discharge pattern of FIG. 7. In the graph illustrated in FIG. 7, the vertical axis represents a current (unit: A), and the horizontal axis represents an elapsed time (unit: second). In FIG. 7, the black squares and the solid line indicate the discharge pattern before adjustment, and the white circles and the alternate long and short dash line indicate the adjusted discharge pattern and a recognition pattern at the time of calculation recognized based on the discharge pattern.

The prediction device 3 calculates a difference between temporally-consecutive current values based on the discharge pattern data before adjustment, thereby obtaining a current change amount in each section. In the discharge pattern data before adjustment, a current value is recorded at each time divided by a constant division time as illustrated in FIG. 2. The prediction device 3 classifies all the sections of the discharge pattern data into a section in which the current change amount is not zero and a section in which the current change amount is zero based on the calculation result. In the discharge pattern of the present example embodiment, sections from 0 seconds to 0.15 seconds and from 0.65 seconds to 0.75 seconds are the sections in which the current change amount is not zero, and sections from 0.3 seconds to 0.65 seconds are the sections in which the current change amount is zero, for example.

In a case where the discharge pattern data includes the constant current period including a plurality of temporally-continuous sections in which the current change amount is zero, the prediction device 3 omits data of an in-between section of the constant current period from the discharge pattern data. In the constant current period, the plurality of temporally-continuous sections included in the constant current period is regarded as a set of sections, and the prediction calculation using the energy storage device model is executed only once for the set of sections.

As illustrated in FIGS. 7 and 8, since 0.3 seconds to 0.65 seconds are the constant current period, data of in-between times from 0.35 seconds to 0.6 seconds is removed, for example. In the prediction calculation, the calculation of the in-between times (in-between sections) is omitted, and the predicted voltage value in a case where a current is carried at a constant current value in the constant current period over a total time obtained by summing the division times of the plurality of sections is obtained.

In the above description, the section in which the change amount of the current value is zero is obtained, but a section in which the change amount of the current value is less than a threshold may be regarded as the constant current section. Furthermore, in a case where the discharge pattern data includes the current change period including the section in which the current change amount is not zero, the prediction device 3 adjusts the current value of the discharge pattern. The prediction device 3 classifies each section included in the current change period into a section in which a current increasing/decreasing direction is not switched and a section in which the current increasing/decreasing direction is switched.

In the section in which the current increasing/decreasing direction is not switched, a consumption capacity of the discharge pattern in this section is calculated, and the current value of the discharge pattern is adjusted so as to correspond to the calculated consumption capacity. The prediction device 3 obtains the adjusted current value such that a consumption capacity in a case where discharge is performed at a constant current value over the division time becomes equal to the consumption capacity of the discharge pattern.

In the section in which the current increasing/decreasing direction is switched, the current value of the discharge pattern corresponding to a switching point at which the current increasing/decreasing direction is switched is directly used as the adjusted current value. In the example illustrated in FIGS. 7 and 8, 0.15 seconds and 0.75 seconds correspond to the switching points, and thus the current value corresponding to each switching point is directly adopted in sections from 0.15 seconds to 0.2 seconds and from 0.75 seconds to 0.8 seconds, for example. The current value is adjusted for each section included in the current change period. As illustrated in FIG. 8, the discharge pattern data in which the number of data points is reduced and the current value is adjusted is generated by the above processing.

The prediction device 3 predicts discharge feasibility with the discharge pattern in a preset calculation cycle based on the obtained adjusted discharge pattern.

The prediction device 3 obtains the predicted voltage value of the energy storage apparatus 1 when discharge is performed with the adjusted discharge pattern using the energy storage device model. The predicted voltage value is calculated for each section of the adjusted discharge pattern. The prediction device 3 predicts the discharge feasibility based on the obtained predicted voltage value. The discharge feasibility is predicted by determining whether or not the predicted voltage value is equal to or more than a preset lower limit voltage. In a case where the predicted voltage value is equal to or more than the lower limit voltage in the entire period related to the discharge pattern, it can be determined that discharge is possible. In a case where the predicted voltage value is less than the lower limit voltage, it can be determined that discharge is impossible.

In the above description, the case where the current carrying pattern is the discharge pattern has been described as an example. In a case where the current carrying pattern is a charge pattern, the charge pattern can be similarly adjusted by adopting the above-described method. By determining whether or not a predicted voltage value when charge is performed with an adjusted charge pattern is equal to or less than a preset upper limit voltage, it is possible to predict charge acceptance feasibility.

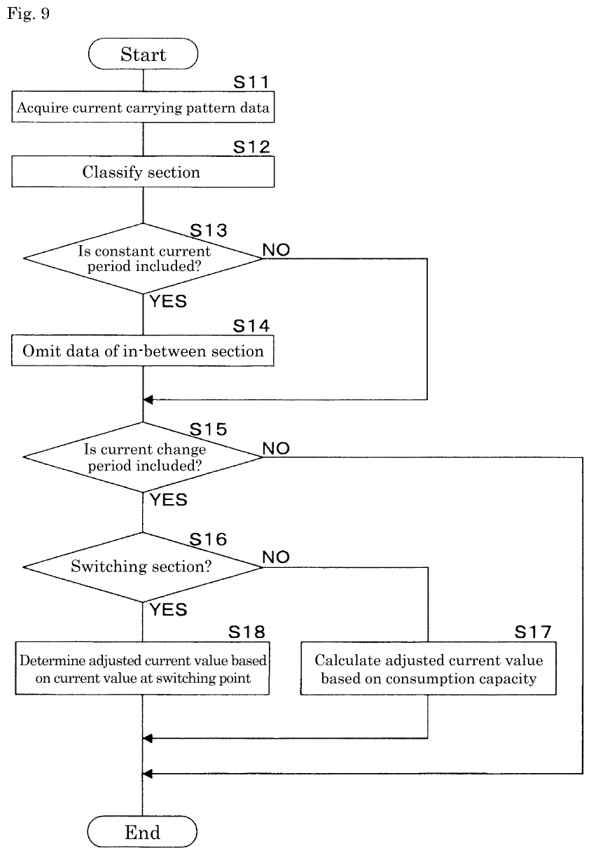

FIG. 9 is a flowchart illustrating an example of an adjustment processing procedure of the current carrying pattern executed by the prediction device 3. The processing in the following flowchart is executed by the controller 31 according to the prediction program 321 stored in the storage assembly 32 of the prediction device 3.

The controller 31 of the prediction device 3 is configured or programmed to acquire current carrying pattern data (step S11). The current carrying pattern data is transmitted from, for example, the host device (for example, the vehicle ECU 71).

The controller 31 is configured or programmed to calculate the current change amount in each section based on the acquired current carrying pattern data, thereby classifying all the sections of the current carrying pattern data into the section in which the current change amount is not zero and the section in which the current change amount is zero (step S12).

The controller 31 is configured or programmed to determine whether or not the current carrying pattern data includes the constant current period based on the classification result (step S13). When determining that the current carrying pattern data does not include the constant current period (S13: NO), the controller 31 advances the processing to step S15.

When determining that the current carrying pattern data includes the constant current period (S13: YES), the controller 31 omits the data of the in-between section of the constant current period from the current carrying pattern data (step S14).

The controller 31 is configured or programmed to determine whether or not the current carrying pattern data includes the current change period based on the classification result (step S15). When determining that the current carrying pattern data does not include the current change period (S15: NO), the controller 31 ends the processing.

When determining that the current carrying pattern data includes the current change period (S15: YES), the controller 31 determines whether or not the section included in the current change period is the section in which the current increasing/decreasing direction is switched (step S16).

When determining that the section is not the section in which the current increasing/decreasing direction is switched, that is, the section is the section in which the current increasing/decreasing direction is not switched (S16: NO), the controller 31 calculates the adjusted current value for adjusting the discharge pattern data based on the consumption capacity in this section (step S17). The controller 31 calculates the consumption capacity of the discharge pattern, and obtains the adjusted current value such that the calculated consumption capacity and the consumption capacity in a case where discharge is performed at the adjusted current value over the division time become equal to each other.

When determining that the section is the section in which the current increasing/decreasing direction is switched (S16: YES), the controller 31 determines the adjusted current value based on the current value of the current carrying pattern corresponding to the switching point of the increasing/decreasing direction (step S18). The controller 31 uses the current value at the switching point as the adjusted current value. The controller 31 executes the processing from step S16 to step S18 for each section included in the current change period. The controller 31 causes the storage assembly 32 to store the discharge pattern defined by the number of data points after omission and the adjusted current values as the adjusted current carrying pattern, and ends the series of processing.

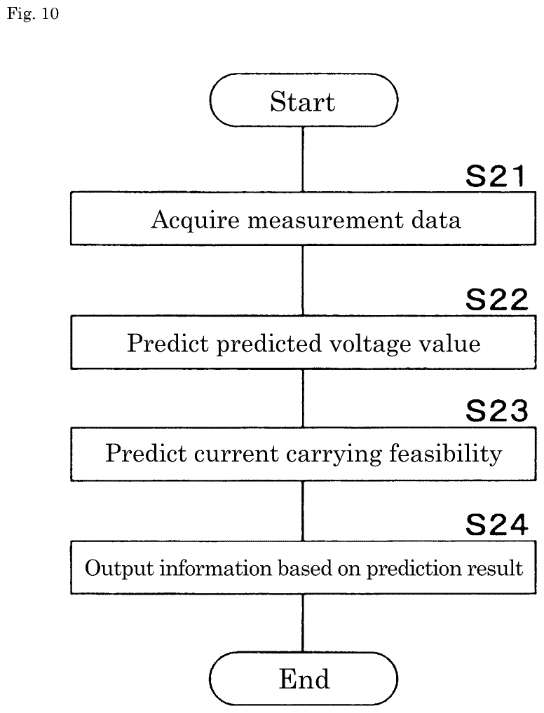

FIG. 10 is a flowchart illustrating an example of a prediction processing procedure of current carrying feasibility executed by the prediction device 3. The controller 31 of the prediction device 3 repeatedly executes the following processing in a preset calculation cycle, for example.

The controller 31 of the prediction device 3 acquires measurement data including a temperature, a current, and a voltage of the energy storage apparatus 1 (step S21).

The controller 31 predicts the predicted voltage value of the energy storage apparatus 1 when a current is carried with the adjusted current carrying pattern based on the acquired measurement data by a function as a first predictor (step S22). The predicted voltage value is predicted for each section using the energy storage device model. The controller 31 collectively calculates the predicted voltage value of the plurality of sections in the constant current period according to the adjusted current carrying pattern data, thereby omitting calculation of the in-between section. In the current change period, the controller 31 predicts the predicted voltage value using the adjusted current value.

The controller 31 predicts the current carrying feasibility with the current carrying pattern based on the obtained predicted voltage value by a function as a second predictor (step S23). The current carrying feasibility is predicted by determining whether or not the obtained predicted voltage value is equal to or more than the preset lower limit voltage or equal to or less than the preset upper limit voltage. In a case where the predicted voltage value is equal to or more than the lower limit voltage or equal to or less than the upper limit voltage, it is predicted that a current can be carried. In a case where the predicted voltage value is not equal to or more than the lower limit voltage or not equal to or less than the upper limit voltage, it is predicted that a current cannot be carried.

The controller 31 outputs information based on the prediction result of the current carrying feasibility to an external device (for example, the vehicle ECU 71) (step S24), and ends the series of processing.

The prediction devices, the prediction methods, and the non-transitory computer-readable media including prediction programs according to example embodiments of the present disclosure can be applied to uses other than the vehicle, and may be applied to, for example, a flying object such as an aircraft, a flying vehicle, or a high altitude platform station (HAPS), or may be applied to a ship or a submarine. The energy storage apparatus 1 may be a high-voltage battery.

According to the present example embodiment, by adjusting the discharge pattern, it is possible to achieve both improvement of the prediction accuracy of the predicted voltage value and the charge-discharge performance and shortening of the prediction time.

It should be considered that the example embodiments disclosed herein are illustrative in all respects and not restrictive. The technical features described in each of the example embodiments can be combined with each other, and the scope of the present invention is intended to include all changes within the claims and the scope equivalent to the claims.

The sequence illustrated in each of the example embodiments is not limited, and within a scope without contradiction, each processing procedure may be executed in a changed order, and a plurality of processes may be executed in parallel. The processing subject of each processing is not limited, and the processing of each device may be executed by another device within a scope without contradiction.

The matters described in each example embodiment can be combined with each other. In addition, the independent claims and the dependent claims set forth below can be combined with each other in all combinations regardless of the form of citation. Furthermore, a form (multi-claim form) in which a claim referring to two or more other claims is described, but the present invention is not limited thereto. Example embodiments of the present invention may be described using a form in which a multi-claim referring to at least one of multi-claims (multi-multi claim) is described.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A prediction device comprising:
a controller configured or programmed to include:
a first predictor configured or programmed to predict voltage behavior of an energy storage device when a current is carried with a current carrying pattern including sections, using an energy storage device model; and
a second predictor configured or programmed to predict charge-discharge performance of the energy storage device based on the voltage behavior predicted by the first predictor; wherein
the first predictor is configured or programmed to predict the voltage behavior for each of the sections, obtained by dividing the current carrying pattern by a time width; and
the first predictor is configured or programmed to stop predicting the voltage behavior in one of the sections in which a current change amount in the current carrying pattern is less than a threshold.

2. The prediction device according to claim 1, wherein one of the sections has a constant current.

3. The prediction device according to claim 1, wherein
the first predictor is configured or programmed to adjust the current carrying pattern based on a consumption capacity or a current at a switching point at which a current increasing/decreasing direction is switched, in one of the sections in which the current change amount in the current carrying pattern is equal to or more than the threshold; and
predict the voltage behavior based on the adjusted current carrying pattern.

4. The prediction device according to claim 3, wherein
one of the sections in which the current change amount in the current carrying pattern is equal to or more than the threshold includes one of the sections in which the current increasing/decreasing direction is switched and one of the sections in which the current increasing/decreasing direction is not switched; and
the first predictor is configured or programmed to adjust the current carrying pattern based on the current at the switching point in the one of the sections in which the current increasing/decreasing direction is switched and the consumption capacity in the one of the sections in which the current increasing/decreasing direction is not switched.

5. The prediction device according to claim 1, wherein the sections of the current carrying pattern include a section in which the current change amount in the current carrying pattern is less than the threshold and a section in which the current change amount is equal to or more than the threshold.

6. The prediction device according to claim 1, comprising an output interface to output the charge-discharge performance of the energy storage device predicted by the second predictor to an external device.

7. An energy storage apparatus comprising:
an energy storage device; and
the prediction device according to claim 1.

8. A prediction method comprising:
predicting voltage behavior of an energy storage device when a current is carried with a current carrying pattern including sections, using an energy storage device model;
predicting charge-discharge performance of the energy storage device based on the predicted voltage behavior;
predicting the voltage behavior for each of the sections, obtained by dividing the current carrying pattern in a time axis direction; and
stopping predicting the voltage behavior in one of the sections in which a current change amount in the current carrying pattern is less than a threshold.

9. A non-transitory computer-readable medium including a prediction program that causes a computer to:
predict voltage behavior of an energy storage device when a current is carried with a current carrying pattern including sections, using an energy storage device model;
predicting charge-discharge performance of the energy storage device based on the predicted voltage behavior;
predicting the voltage behavior for each of the sections, obtained by dividing the current carrying pattern in a time axis direction; and
stopping predicting the voltage behavior in one of the sections in which a current change amount in the current carrying pattern is less than a threshold.

10. A prediction device comprising:
a controller configured or programmed to include:
a first predictor configured or programmed to predict voltage behavior of an energy storage device when a current is carried with a current carrying pattern including sections, using an energy storage device model; and
a second predictor configured or programmed to predict charge-discharge performance of the energy storage device based on the voltage behavior predicted by the first predictor; wherein
the first predictor is configured or programmed to divide the current carrying pattern into a plurality of periods and predict the voltage behavior for each of the periods; and
a time width of a period in which a current change amount in the current carrying pattern is less than a threshold is longer than a time width of a period in which the current change amount in the current carrying pattern is equal to or more than the threshold.
